(19) United States
(12) Patent Application Publication
(10) Pub. No.: US 2026/0323988 A1
(43) Pub. Date: Oct. 15, 2026

(54) NITRIDE SEMICONDUCTOR DEVICE

(71) Applicant: FUJI ELECTRIC CO., LTD., Kawasaki-shi (JP)

(72) Inventor: Ryo TANAKA, Tokyo (JP)

(73) Assignee: FUJI ELECTRIC CO., LTD., Kawasaki-shi (JP)

(21) Appl. No.: 19/545,753

(22) Filed: Feb. 20, 2026

(30) Foreign Application Priority Data
Apr. 15, 2025 (JP) 2025-066909

(51) Int. Cl. H10D 30/66; H10D 62/10; H10D 62/85; H02M 3/156

(52) U.S. Cl. CPC H10D 30/66; H10D 62/111; H10D 62/8503; H02M 3/156

(57) ABSTRACT

There is provided a nitride semiconductor device including a switching element capable of suppressing an increase in SW loss even when driven at a high driving frequency. The nitride semiconductor device includes: a nitride semiconductor substrate; and a vertical switching element provided on the nitride semiconductor substrate. The vertical switching element has a product of on-resistance Ron and the gate charge amount Qg (Ron·Qg) of 2Ω·nC or less and is driven at a driving frequency of 100 kHz or more.

### CROSS-REFERENCE TO RELATED APPLICATION

This application claims benefit of priority under 35 USC 119 based on Japanese Patent Application No.2025-066909 filed on Apr. 15, 2025, the entire contents of which are incorporated by reference herein.

### BACKGROUND OF THE INVENTION

### 1. Field of the Invention

The present disclosure relates to a nitride semiconductor device.

### 2. Description of the Related Art

By increasing the driving frequency of a switching circuit, such as a DC/DC converter, the inductance or the capacitance of peripheral members can be reduced, which allows a device size reduction and a cost reduction.

On the other hand, when the driving frequency is increased, a switching (SW) loss occurring in a switching element increases.

It is known that the performance of a switching element formed in SiC is specified by the driving frequency and Ron·Qg (see JP 7394944 B (patent literature 1), for example).

In addition, the following non-patent literature 1 is known: Naoki Torii et al. "Low RonCrss Nomally-off Vertical GaN Transistor on GaN Substrate Using p-GaN Shield Structure for High-Power and High-Speed Switching" 2024 IEEE International Electron Devices Meeting (IEDM) DOI: 10.1109/IEDM50854.2024.10873538 Internet <URL: https://ieeexplore.ieee.org/document/10873538>

### SUMMARY OF THE INVENTION

A switching element capable of suppressing an increase in SW loss even when driven at a high driving frequency has been demanded.

### SOLUTION TO PROBLEM

It is an object of the present disclosure to provide a nitride semiconductor device including a switching element capable of suppressing an increase in SW loss even when driven at a high driving frequency.

To solve the above-described problem, a nitride semiconductor device according to one aspect of the present disclosure includes: a nitride semiconductor substrate; and a vertical switching element provided on the nitride semiconductor substrate. The vertical switching element has a product of on-resistance Ron and a gate charge amount Qg (Ron·Qg) of 2Ω·nC or less and is driven at a driving frequency of 100 kHz or more.

### BRIEF DESCRIPTION OF THE DRAWINGS

FIG. 1 is a cross-sectional view illustrating a configuration example 1 of a GaN semiconductor device according to this embodiment;

FIG. 2 is a cross-sectional view illustrating a configuration example 2 of the GaN semiconductor device according to this embodiment;

FIG. 3 is a cross-sectional view illustrating a configuration example 3 of the GaN semiconductor device according to this embodiment;

FIG. 4 is a table view showing simulation results of Ron·Qg in the configuration examples 1, 2 of this embodiment;

FIG. 5 is a graph showing the simulation results of on-resistance in the configuration examples 1, 2 of this embodiment and a comparative example;

FIG. 6 is a graph showing the results of simulating dependence on driving frequency of SW loss in the configuration examples 1, 2 of this embodiment and the comparative example; and

FIG. 7 is a circuit diagram illustrating an SW circuit according to an application example of this embodiment.

### DETAILED DESCRIPTION

Hereinafter, an embodiment of the present disclosure (this embodiment) is described. In the description of the drawings below, the same or similar reference signs are attached to the same or similar portions. It should be noted that the drawings are schematic, and the relation between the thickness and the plane dimension, the thickness ratio of each device or each member, and the like are different from the actual relation, thickness ratio, and the like. Therefore, the specific thickness and dimension should be determined in consideration of the description below. It is a matter of course that the drawings include portions different in mutual dimensional relations and ratios.

In the description below, the directions are sometimes described using words of an X-axis direction, a Y-axis direction, and a Z-axis direction. For example, the X-axis direction and the Y-axis direction are directions parallel to a front surface 10a of a GaN substrate 10 described later. The X-axis direction and the Y-axis direction each are also referred to as the horizontal direction. The Z-axis direction is a direction perpendicularly intersecting the front surface 10a of the GaN substrate 10 and is also the thickness direction of the GaN substrate 10. The X-axis direction, the Y-axis direction, and the Z-axis direction are orthogonal to each other.

In the description below, the positive direction of the Z-axis is sometimes referred to as "upper" and the negative direction of the Z-axis is sometimes referred to as "lower". However, the "upper" and the "lower" do not always mean the vertical direction relative to the ground. More specifically, the directions of "upper" and "lower" are not limited to the direction of gravity. "Upper" and "lower" are merely convenient expressions for specifying the relative positional relationships of regions, layers, films, substrates, and the like, and do not limit the technical idea of the present disclosure. For example, it is a matter of course that, when the paper is rotated 180 degrees, "upper" becomes "lower" and "lower" become "upper".

In the description below, + and - attached to p and n indicating the conductivity type mean that semiconductor regions attached by + and - have a relatively higher or lower impurity concentration than that of semiconductor regions not attached by + and -, respectively. However, even when semiconductor regions are attached by the same p and p (or n and n), it does not mean that the impurity concentrations of the semiconductor regions are exactly the same.

### Embodiment

### Configuration Example 1

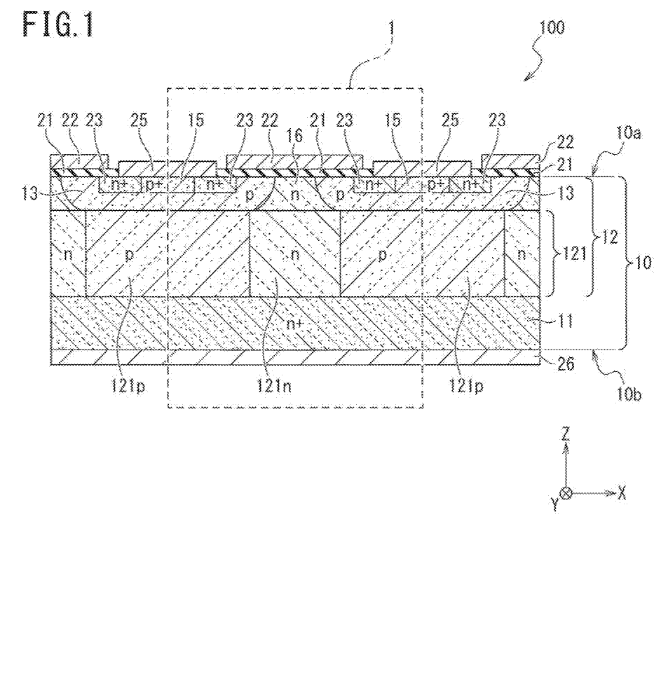

FIG. 1 is a cross-sectional view illustrating a configuration example 1 of a GaN semiconductor device 100 according to this embodiment. As illustrated in FIG. 1, the GaN semiconductor device 100 includes a gallium nitride substrate (one example of the "nitride semiconductor" of the present disclosure; hereinafter GaN substrate) 10 and a plurality of vertical MOSFETs (Metal Oxide Semiconductor Field Effect Transistor; one example of the "vertical switching element" of the present disclosure) 1 provided on the GaN substrate 10. The plurality of vertical MOSFETs 1 is repeatedly provided in one direction (e.g., X-axis direction). One vertical MOSFET 1 is a repeating unit structure, and the unit structures are arranged side by side in one direction.

The vertical MOSFET 1 has a 1200 V-class gate-off breakdown voltage, for example. The vertical MOSFET 1 is driven (i.e., turned on/off) at a driving frequency of 100 kHz or more. The vertical MOSFET 1 is a vertical MOSFET that is a planar gate type and has drift regions 121 of a super junction structure (hereinafter also referred to as an SJ structure). Hereinafter, the vertical MOSFET 1 is described in detail.

The GaN substrate 10 has an n⁺-type GaN single crystal substrate 11 and a GaN layer 12 provided on the GaN single crystal substrate 11. The GaN single crystal substrate 11 is an n⁺-type c-plane GaN single crystal substrate, for example. The n-type impurity contained in the GaN single crystal substrate 11 is one or more of silicon (Si), oxygen (O), and germanium (Ge), for example. As one example, the GaN single crystal substrate 11 contains Si as the n-type impurity, and the impurity concentration of Si in the GaN single crystal substrate 11 is 5 × 10¹⁷ cm⁻³ or more.

The GaN single crystal substrate 11 may be a low-dislocation freestanding substrate having a dislocation density of less than 1 × 10⁷ cm⁻². Due to the fact that the GaN single crystal substrate 11 is a low-dislocation freestanding substrate, the dislocation density of the GaN layer 12 formed on the GaN single crystal substrate 11 is also low. The use of the low-dislocation freestanding substrates allows a reduction in leakage current in a large-area power device, even when the power device is formed on the GaN substrate 10. This allows a manufacturing device to manufacture the power device with a high non-defective rate. Further, ion-implanted impurities can be prevented from deeply diffusing along the dislocation in heat treatment.

The GaN layer 12 is a single crystal GaN layer epitaxially grown on one surface of the GaN single crystal substrate 11. The GaN layer 12 is provided with drift regions 121 of the SJ structure. The SJ structure is described later.

The GaN substrate 10 has the front surface 10a (one example of the "first surface" of the present disclosure) and a rear surface 10b (one example of the "second surface" of the present disclosure) positioned on the side opposite to the front surface 10a. The front surface of the GaN layer 12 is equivalent to the front surface 10a of the GaN substrate 10, and the rear surface of the GaN single crystal substrate 11 is equivalent to the rear surface 10b of the GaN substrate 10.

The vertical MOSFET 1 is a double-diffused MOSFET (DMOS) and has p-type well regions 13 provided on the side of the front surface 10a of the GaN substrate 10, p⁺-type contact regions 15 positioned inside the well regions 13, n⁺-type source regions 23 positioned inside the well regions 13, and an n-type (or n⁻-type) JFET region 16 positioned outside the well regions 13. In the GaN layer 12, the regions excluding the well regions 13, the contact regions 15, the source regions 23, and the JFET region 16 are the drift regions 121.

The drift regions 121 are in contact with the n⁺-type GaN single crystal substrate 11. The vertical MOSFET 1 has a gate insulating film 21 provided on the side of the front surface 10a of the GaN substrate 10, a gate electrode 22 provided on the gate insulating film 21, source electrodes 25 provided on the side of the front surface 10a of the GaN substrate 10 and in contact with the n⁺-type source regions 23 and the p⁺-type contact regions 15, and a drain electrode 26 provided on the side of the rear surface 10b of the GaN substrate 10 and in contact with the n⁺-type GaN single crystal substrate 11.

The well regions 13 are, for example, p-type layers formed by ion implantation of a p-type impurity, such as Mg, to the side of the front surface 10a of the GaN substrate 10 and activation of the p-type impurity by heat treatment. The well regions 13 contain, for example, Mg as the p-type impurity at a concentration of 1 × 10¹⁷ cm⁻³ or more and 3 × 10¹⁸ cm⁻³ or less. The well regions 13 face the front surface 10a of the GaN substrate 10 and are in contact with the gate insulating film 21.

The contact regions 15 are, for example, p⁺-type layers formed by ion implantation of a p-type impurity, such as Mg, to the side of the front surface 10a of the GaN substrate 10 and activation of the p-type impurity by heat treatment. The contact regions 15 contain Mg as the p-type impurity at a concentration of 3 × 10¹⁸ cm⁻³ or more and 1 × 10²¹ cm⁻³ or less and preferably contains Mg at a concentration of 1 × 10¹⁹ cm⁻³ or more and 2 × 10²⁰ cm⁻³ or less. The contact regions 15 face the front surface 10a of the GaN substrate 10. The contact regions 15 are positioned inside the well regions 13 and are in contact with the well regions 13. The contact regions 15 are also in contact with the source regions 23.

The well regions 13 are connected to the source electrodes 25 through the contact regions 15. This fixes the potential of the well regions 13 to the potential of the source electrodes 25 (e.g., reference potential, such as ground potential (GND)).

The JFET region 16 is a region sandwiched from both sides by the p-type well regions 13, which form a pair, adjacent to each other in the horizontal direction in the GaN layer 12. In the configuration example 1, the JFET region 16 contains, for example, Si as an n-type impurity at a concentration of 5 × 10¹⁵ cm⁻³ or more and 2 × 10¹⁸ cm⁻³ or less. As the n-type impurity, oxygen (O) may be used in place of Si.

The source regions 23 are n⁺-type layers formed by ion implantation of an n-type impurity, such as Si or O, to the side of the front surface 10a of the GaN substrate 10 and activation of the n-type impurity by heat treatment. The source regions 23 contain, for example, Si as the n-type impurity at a concentration of 1 × 10¹⁹ cm⁻³ or more and 5 × 10²⁰ cm⁻³ or less. The source regions 23 are provided in the well regions 13 under both sides of the gate electrode 22 and face the front surface 10a of the GaN substrate 10. The source regions 23 are positioned inside the well regions 13 and are in contact with the well regions 13.

The gate insulating film 21 is, for example, an SiO₂ film and has a thickness of 100 nm. The gate electrode 22 is adjacent to a region where a channel is formed (hereinafter "channel region") through the gate insulating film 21. The gate electrode 22 is opposed to the well regions 13 and the source regions 23 through the gate insulating film 21. The gate electrode 22 contains metals, such as Al, titanium (Ti), nickel (Ni), and tungsten (W), or polysilicon doped with impurities. The gate electrode 22 may also contain silicides, such as WSi and NiSi.

The source electrodes 25 are connected to the n⁺-type source regions 23 and the p⁺-type contact regions 15 in an ohmic manner. The drain electrode 26 is connected to the rear surface 10b of the GaN substrate 10 (i.e., rear surface of the n⁺-type GaN single crystal substrate 11) in an ohmic manner.

The source electrodes 25 and the drain electrode 26 contain Al or Al-Si alloys, Ni, Ni alloys, Ti-Al alloys, Ni-gold (Au) alloys, and the like. The source electrodes 25 each may also have a barrier metal layer between the source electrode 25 and the source region 23. The drain electrode 26 may have a barrier metal layer between the drain electrode 26 and the n⁺-type GaN single crystal substrate 11. The barrier metal layer may contain Ti (titanium).

More specifically, the source electrodes 25 and the drain electrode 26 may be a stack of a Ti layer and an Al layer or a stack of a Ti layer and an Al-Si alloy layer. The source electrodes 25 and the drain electrode 26 may contain materials different from each other and may have different stacked structures. The source electrodes 25 may be electrodes that also serve as source pads which are not illustrated or may be electrodes provided separately from a source pad. The drain electrode 26 may be an electrode that also serves as a drain pad which is not illustrated or may be an electrode provided separately from a drain pad.

As illustrated in FIG. 1, the vertical MOSFET 1 is provided with the drift regions 121 of the SJ structure in the GaN layer 12. The drift regions 121 of the SJ structure have an n-type column 121n and p-type columns 121p. The column may be rephrased as a pillar. The n-type column 121n and the p-type columns 121p are adjacent to each other in the horizontal direction (e.g., X-axis direction). The p-type columns 121p each are provided from the bottom of the well region 13 to the rear surface of the GaN layer 12 and are in contact with the well region 13 and the GaN single crystal substrate 11. The n-type column 121n is positioned between one column 121p and the other column 121p adjacent to each other in the horizontal direction. Although this example has a layout in which the p-type columns 121p of the SJ structure are provided at the bottoms of the well regions 13, this layout is an option and a different layout may be used.

The columns 121p may have the same or substantially the same p-type impurity concentration as that of the p-type well regions 13. Alternatively, the columns 121p may have a p-type impurity concentration higher than that of the well regions 13 and a p-type impurity concentration lower than that of the p⁺-type contact regions 15. As one example, the columns 121p contain Mg at a concentration of 2 × 10¹⁶ cm⁻³ or more and 2 × 10¹⁷ cm⁻³ or less as the p-type impurity concentration.

The column 121n may have the same or substantially the same n-type impurity concentration as that of the JFET region 16. Alternatively, the column 121n may have an n-type impurity concentration higher than that of the JFET region 16 and an n-type impurity concentration lower than that of the n⁺-type source regions 23. As one example, the columns 121n contain Si at a concentration of 2 × 10¹⁶ cm⁻³ or more and 2 × 10¹⁷ cm⁻³ or less as the n-type impurity concentration. As the n-type impurity, oxygen (O) may be used in place of Si.

The vertical MOSFET 1 includes the drift regions 121 of the SJ structure, and therefore the n-type impurity concentration of the n-type column 121n can be increased while a reduction in breakdown voltage is suppressed, and drift resistance can be reduced. This allows a further reduction in on-resistance of the vertical MOSFET. By further reducing the on-resistance, the contribution of channel resistance in the on-resistance further increases.

The vertical MOSFET 1 is a GaN-vertical MOSFET provided on the GaN substrate 10. Therefore, the channel mobility can be increased (i.e., channel resistance can be reduced) and the on-resistance can be reduced as compared with those of an SiC-vertical MOSFET provided on a silicon carbide (SiC) substrate. As shown in simulation results (e.g., FIG. 5) described later, the ratio of the channel resistance to the on-resistance (i.e., element resistance) can be reduced. Thus, the product of on-resistance Ron and a gate charge amount Qg (Ron·Qg) can be set to be 2Ω·nC or less.

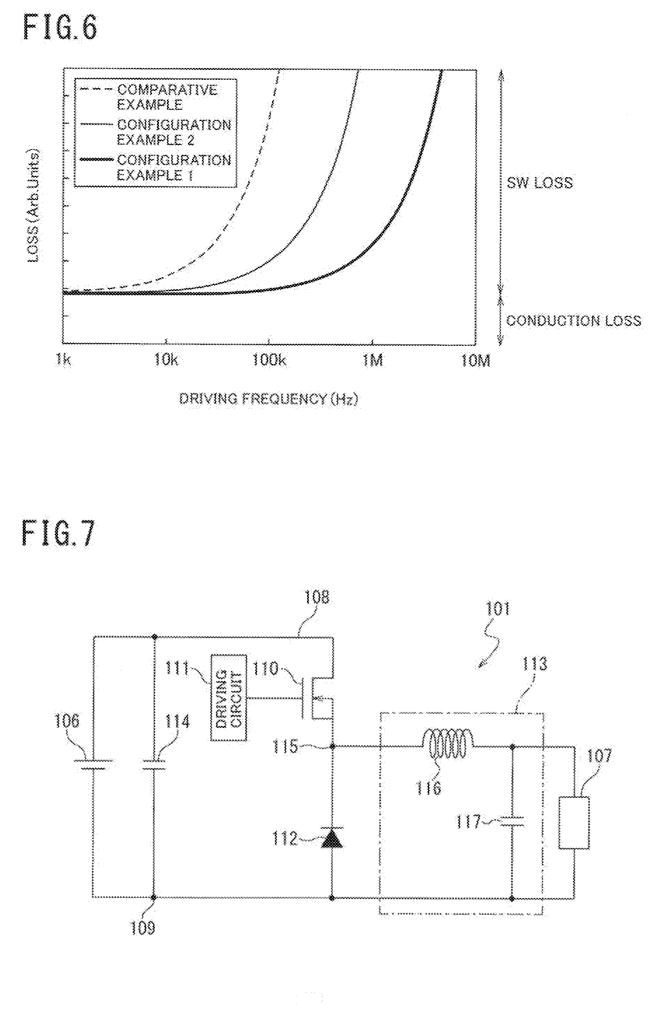

Due to the fact that the drift regions 121 of the SJ structure are provided, the on-resistance Ron can be further reduced. The vertical MOSFET 1 is not a trench-gate type but a planar gate type, and therefore the gate charge amount Qg can be reduced. Thus, the Ron·Qg can be further reduced. By setting the Ron·Qg to 2 Ω·nC or less and preferably 1 Ω·nC or less, an increase in switching (SW) loss can be suppressed even when the driving frequency is 100 kHz or more as shown in the simulation results (e.g., FIG. 6) described later.

The cell pitch (i.e., arrangement spacing) of the vertical MOSFETs 1 is not particularly limited, and is 2.6 μm as one example. The channel length of the vertical MOSFET 1 is also not particularly limited, and is 0.25 μm as one example.

### Configuration Example 2

FIG. 2 is a cross-sectional view illustrating a configuration example 2 of the GaN semiconductor device 100 according to this embodiment. As illustrated in FIG. 2, the GaN semiconductor device 100 may include the GaN substrate 10 and a plurality of vertical MOSFETs 1A provided on the GaN substrate 10. As with the vertical MOSFET 1 illustrated in FIG. 1, the vertical MOSFET 1A illustrated in FIG. 2 is one example of the "vertical switching element" of the present disclosure. The vertical MOSFET 1A is different from the vertical MOSFET 1 illustrated in FIG. 1 in that the drift region 121 does not have the SJ structure (i.e., Non-SJ structure).

The vertical MOSFET 1A is a vertical MOSFET that is a planar gate type and does not have the drift region of the SJ structure. The drift region 121 possessed by the vertical MOSFET 1A contains only an n⁻-type layer. In the configuration example 2, the drift region 121 contains, for example, Si as the n-type impurity at a concentration of 1 × 10¹⁵ cm⁻³ or more and 5 × 10¹⁶ cm⁻³ or less. The JFET region 16 contains, for example, Si as the n-type impurity at a concentration of 5 × 10¹⁵ cm⁻³ or more and 2 × 10¹⁸ cm⁻³ or less and has an impurity concentration higher than the impurity concentration of the drift region 121. As the n-type impurity, oxygen (O) may be used in place of Si.

In the vertical MOSFET 1A, the configurations other than the above are the same as those of the vertical MOSFET 1. The vertical MOSFET 1A has a 1200 V-class gate-off breakdown voltage, for example. The vertical MOSFET 1A is driven at a driving frequency of 100 kHz or more. The product of the on-resistance Ron and the gate charge amount Qg (Ron·Qg) of the vertical MOSFET 1A is 2 Ω·nC or less and more preferably 1 Ω·nC or less.

### Configuration Example 3

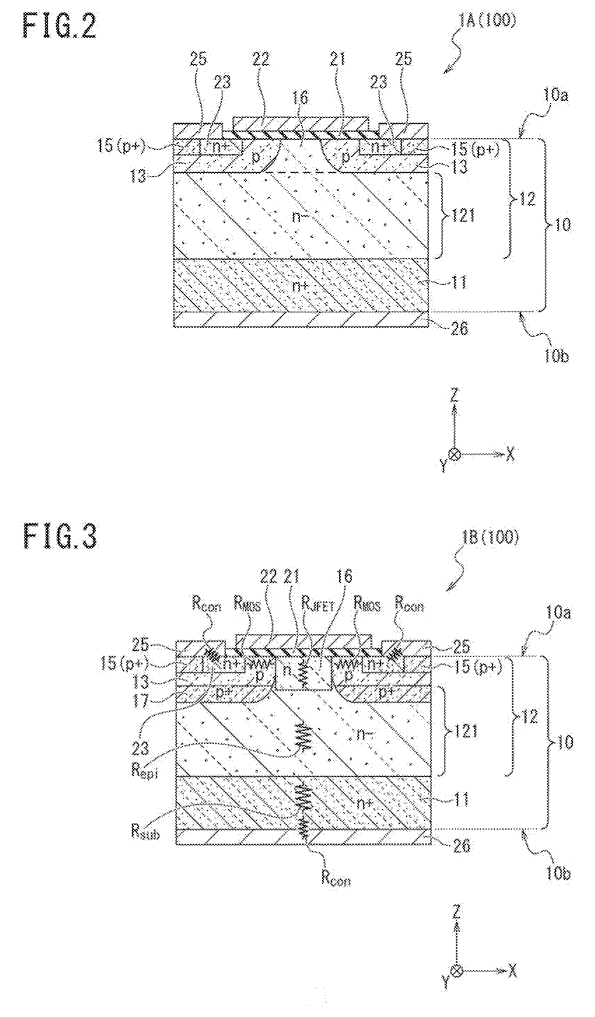

FIG. 3 is a cross-sectional view illustrating a configuration example 3 of the GaN semiconductor device 100 according to this embodiment. As illustrated in FIG. 3, the GaN semiconductor device 100 may include the GaN substrate 10 and a plurality of vertical MOSFETs 1B provided on the GaN substrate 10. As with the vertical MOSFETs 1, 1A illustrated in FIGS. 1, 2, respectively, the vertical MOSFET 1B illustrated in FIG. 3 is one example of the "vertical switching element" of the present disclosure. The vertical MOSFET 1B is different from the vertical MOSFET 1A illustrated in FIG. 2 in that the vertical MOSFET 1B has p⁺-type regions 17 provided in the GaN layer 12.

In the configuration example 3, the JFET region 16 contains, for example, oxygen (O) as the n-type impurity at a concentration of 5 × 10¹⁵ cm⁻³ or more and 2 × 10¹⁸ cm⁻³ or less. As the n-type impurity, Si may be used in place of oxygen (O). The vertical MOSFET 1B has a higher n-type impurity concentration in the JFET region 16 than that of the vertical MOSFET 1A, and therefore the on-resistance Ron can be lowered. The p⁺-type regions 17 are positioned directly under the p-type well regions 13 and are in contact with the well regions 13. A depletion layer formed between the p⁺-type regions 17 and the n⁻-type GaN layer 12 can increase the gate-off breakdown voltage. In the vertical MOSFET 1B, the configurations other than the above are the same as those of the vertical MOSFET 1A.

The vertical MOSFET 1B has a 1200 V-class gate-off breakdown voltage, for example. The vertical MOSFET 1B is driven at a driving frequency of 100 kHz or more. The product of the on-resistance Ron and the gate charge amount Qg (Ron·Qg) of the vertical MOSFET 1B is 2 Ω·nC or less and more preferably 1 Ω·nC or less.

FIG. 3 illustrates the main resistance components in a current path of the vertical MOSFET 1B (contact resistance R_{con}, substrate resistance R_{sub}, epi resistance (drift resistance) Rₑₚᵢ, JFET resistance R_{JFET}, and MOS channel resistance R_{MOS}). These resistance components are described later with reference to FIG. 5.

### Simulation results

(1) Ron·Qg

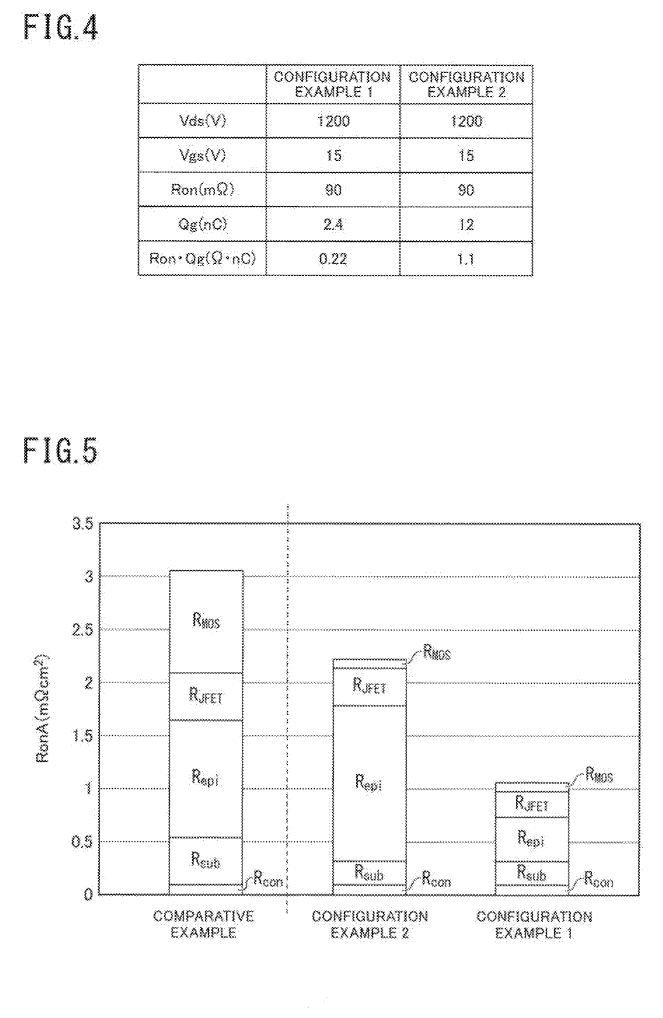

FIG. 4 is a table view illustrating the simulation results of the Ron·Qg in the configuration examples 1, 2 of the present disclosure. The configuration example 1 is the vertical MOSFET 1 illustrated in FIG. 1. The configuration example 2 is the vertical MOSFET 1A illustrated in FIG. 2. As illustrated in FIG. 4, in this simulation, the source-drain breakdown voltage Vds (i.e., gate-off breakdown voltage) was set to 1200 (V), and the on-resistance Ron when the gate-source voltage Vgs was 15 V was set to 90 (mΩ). Under the set conditions, the Ron·Qg (Ω·nC) of the configuration examples 1, 2 was simulated, and then the results were obtained that the Ron·Qg of the configuration example 1 was 0.22 Ω·nC and the Ron·Qg of the configuration example 2 was 1.1 Ω·nC.

For the vertical MOSFET 1B illustrated in FIG. 3 (hereinafter configuration example 3), the simulation under the above-described conditions was not carried out. In the configuration example 3, the concentration of the JFET region 16 is higher than that of the configuration example 2 and the on-resistance Ron is lower that of the configuration example 2. Therefore, when the simulation under the same conditions was performed, the Ron·Qg value is considered to be lower in the configuration example 3 than in the configuration example 2.

(2) Channel resistance/Element resistance ratio

FIG. 5 is a graph showing the simulation results of the on-resistance in the configuration examples 1, 2 of the present disclosure and a comparative example. In this simulation, the breakdown voltage of the vertical MOSFETs was set to 1200 V and the environmental temperature at which the vertical MOSFETs are driven was set to 175°C. The comparative example was set to an SiC-vertical MOSFET in which a substrate and an epitaxial layer contain silicon carbide (SiC) and the other configurations other than the above have the same configurations as those of the configuration example 2. On-resistance RonA is on-resistance normalized by the area, and is specifically a value obtained by multiplying the on-resistance Ron by the area of an element (i.e., chip size).

As illustrated in FIG. 3, the on-resistance of the vertical MOSFET contains, as the main resistance components, contact resistance R_{con}, substrate resistance R_{sub}, epitaxial layer resistance (hereinafter epi-resistance; also referred to as drift resistance) Rₑₚᵢ, JFET resistance R_{JFET}, and MOS channel resistance R_{MOS}. The contact resistance R_{con} contains contact resistance between a drain electrode and the rear surface of a substrate and contact resistance between a source electrode and the front surface of a substrate. As illustrated in FIG. 5, the configuration examples 1, 2 have the MOS channel resistance R_{MOS} markedly smaller than that of the comparative example, and therefore the simulation results were obtained that the on-resistance RonA is sufficiently low. In the configuration examples 1, 2, the channel resistance R_{MOS} values were lower than the contact resistance R_{con} value (i.e., the total value of contact resistance between the drain electrode 26 and the rear surface 10b of the GaN substrate 10 and contact resistance between the source electrode 25 and the front surface 10a of the GaN substrate 10). In the comparative example, the channel resistance R_{MOS} value was larger than the contact resistance R_{con} value.

Further, the simulation results were obtained that the configuration example 1 having the drift regions 121 of the SJ structure have the on-resistance much lower than that in the configuration example 2 because not only the channel resistance R_{MOS} but the Epi resistance (drift resistance) Rₑₚᵢ is also markedly low. Specifically, the simulation results were obtained that the on-resistance in the configuration example 1 can be reduced to about half of that of the configuration example 2. Further, the simulation results were obtained that the ratio of the channel resistance R_{MOS} to the on-resistance RonA (i.e., element resistance) is 10% or less in the configuration example 1 and 5% or less in the configuration example 2, which are markedly lower values than the value of the comparative example.

(3) Dependence on driving frequency of SW loss

FIG. 6 is a graph showing the results of simulating the dependence on driving frequency of switching (SW) loss in the configuration examples 1, 2 of the present disclosure and the comparative example. In this simulation, the on-resistance Ron was set to the same value in the configuration examples 1, 2 and the comparative example. When the Ron is set to the same value, elements having a larger area tend to have an increase in capacitance and an increase in SW loss. With an increase in driving frequency, the SW loss tends to increase.

As illustrated in FIG. 6, the simulation results were obtained that the dependence on driving frequency of SW loss is lower in the configuration examples 1, 2 than in the comparative example (i.e., Even when the driving frequency increases, the increase in SW loss can be suppressed low.). Further, the simulation results were obtained that the dependence on driving frequency of SW loss is much lower in the configuration example 1 than in the configuration example 2. The simulation results were obtained that the configuration examples 1, 2 have markedly lower dependence on driving frequency of SW loss when the driving frequency is in the range of 100 kHz or more and 10 MHz or less, and particularly the configuration example 1 has more markedly lower dependence on driving frequency of SW loss when the driving frequency is in the range of 500 kHz or more and 10 MHz or less, than that of the comparative example.

### Specific example

Based on the simulation results and the like above, a specific example (one example) of each of the Ron, the Qg, the driving frequency, and the like in the configuration examples 1 to 3 is given.

(1) Each value of Ron·Qg

As one example, when the Ron is 90 mΩ as illustrated in FIG. 4, the Qg of the configuration example 1 is preferably 1 nC or more and 10 nC or less, and the Qg in the configuration example 2 is preferably 10 nC or more and 20 nC or less. Thus, the Ron·Qg is 2Ω·nC or less and more preferably 1Ω·nC or less. However, when the chip area is changed, the Ron and the Qg change due to trade-off, and therefore the numerical value range of the Qg is in the case where the Ron is 90 mΩ. The Ron is not limited to 90 mΩ. The lower limit value of the Ron may be larger than 0 (zero), and may be 0.4 mΩ, for example.

(2) RonA

As illustrated in FIG. 5, the on-resistance (RonA) normalized by the area is preferably 2.5 mΩcm² or less at 175°C and more preferably 1.5 mΩcm² or less at 175°C.

(3) Channel resistance/Element resistance ratio

As illustrated in FIG. 5, the ratio of the channel resistance R_{MOS} to the on-resistance RonA (i.e., element resistance) is preferably 20% or less, preferably 10% or less, and still more preferably 5% or less. By reducing this ratio, an increase in on-resistance can be suppressed low even when the area of an element (chip size) is reduced, and loss due to the on-resistance can be easily suppressed low.

(4) Driving frequency

In this embodiment, the driving frequency is 100 kHz or more, and may be 200 kHz or more, or may be 500 kHz or more. The driving frequency may be 10 MHz or less, may be 2 MHz or less, or may be 1 MHz or less. According to this embodiment, the ratio of the SW loss to the total loss (e.g., total of conduction loss and SW loss) can be suppressed low even at high frequencies of 100 kHz or more as illustrated in FIG. 5. This allows operation at a high frequency and with high output.

(5) JFET resistance

The JFET resistance R_{JFET} in the configuration example 3 is preferably 0.5 mΩcm² or less and more preferably 0.3 mΩcm² or less.

### Advantageous effects of this embodiment

As described above, the GaN semiconductor device 100 according to this embodiment includes the GaN substrate 10 and a vertical switching element (e.g., one or more of the vertical MOSFETs 1, 1A, and 1B) provided on the GaN substrate 10. The vertical switching element has the product of the on-resistance Ron and the gate charge amount Qg (Ron·Qg) of 2Ω·nC or less and more preferably 1Ω·nC or less and is driven at a driving frequency of 100 kHz or more.

This allows a reduction in dependence on driving frequency of switching (SW) loss even when the vertical switching element is driven at a high driving frequency of 100 kHz or more. As illustrated in FIG. 6, for example, the configuration examples 1, 2 can markedly lower the dependence on driving frequency of SW loss when the driving frequency is in the range of 100 kHz or more and 10 MHz or less, and particularly the configuration example 1 can more markedly lower the dependence on driving frequency of SW loss when the driving frequency is in the range of 500 kHz or more and 1 MHz or less, as compared with the comparative example.

Thus, even in the case of a high driving frequency of 100 kHz or more, the dependence on driving frequency of SW loss can be lowered and an increase in SW loss can be suppressed. This allows switching operation at a high frequency and with high output. The vertical switching element according to this embodiment can become an extremely useful element in the field of high-speed switching technology, such as advanced air mobility (driving frequency is 100 kHz or more) and high-speed charging (driving frequency is 1 MHz or more), which are expected to further technologically develop in the future.

### Application examples

FIG. 7 is a circuit diagram illustrating a switching (SW) circuit 101 according to an application example of this embodiment. The SW circuit 101 illustrated in FIG. 7 is, for example, a DC/DC converter that steps down a power supply voltage output from a DC power supply 106 and outputs the stepped-down voltage to a load 107.

The SW circuit 101 includes a switching element 110, a driving circuit 111, a rectifying diode 112, a smoothing circuit 113, and an electrolytic capacitor 114. A positive (+) side terminal of the DC power supply 106 is connected to a power supply potential line 108. A negative (−) side terminal of the DC power supply 106 is connected to a ground potential line 109. The electrolytic capacitor 114 is connected between the power supply potential line 108 and the ground potential line 109. The switching element 110 contains the vertical MOSFET 1 (configuration example 1) illustrated in FIG. 1, the vertical MOSFET 1A (configuration example 2) illustrated in FIG. 2, or the vertical MOSFET 1B (configuration example 3) illustrated in FIG. 3, for example.

The drain terminal of the switching element 110 is connected to the power supply potential line 108 and the source terminal thereof is connected to the cathode of the diode 112. The anode of the diode 112 is connected to the ground potential line 109. To the gate terminal of the switching element 110, the driving circuit 111 is connected. The driving circuit 111 supplies a control signal to switch the switching element 110 (i.e., a signal to turn on/off the gate). This control signal is a high-frequency signal of 100 kHz or more, and may be a high-frequency signal of 100 kHz or more and 10 MHz or less, or may be a high-frequency signal of 500 kHz or more and 10 MHz or less, for example. The control signal may be a square wave signal or a sinusoidal signal.

The smoothing circuit 113 smooths a voltage delivered to a node 115 between the switching element 110 and the diode 112 and supplies the smoothed voltage to the load 107. The smoothing circuit 113 contains a choke coil 116 and an electrolytic capacitor 117. The choke coil 116 has one terminal connected to the node 115 and the other terminal connected to the load 107. The electrolytic capacitor 117 is connected between the other terminal of the choke coil 116 and the ground potential line 109.

When the switching element 110 is turned on by the supply of the control signal from the driving circuit 111 to the gate of the switching element 110, a current supplied from the DC power supply 106 flows into the choke coil 116. Thus, energy is stored in the choke coil 116 and the electrolytic capacitor 117 is charged, increasing the voltage supplied to the load 107. Thereafter, when the switching element 110 is turned off by the control signal from the driving circuit 111, the choke coil 116 tries to keep current flowing from the node 115 toward the load 107, and therefore current flows through the diode 112 and voltage supplied to the load 107 is held. The potential appearing on the other terminal side (load 107 side) of the choke coil 116 is smoothed by the electrolytic capacitor 117, so that stable voltage is supplied to the load 107.

By such operation, the DC voltage output from the DC power supply 106 is stepped down in accordance with the duty ratio of the control signal given to the gate terminal of the switching element 110, and the stepped-down DC voltage is supplied to the load 107. In the SW circuit 101, the vertical switching element (e.g., configuration example 1, 2, or 3) according to this embodiment is applied to the switching element 110, and therefore the increase in SW loss can be suppressed even when the vertical switching element is driven at a high driving frequency of 100 kHz or more.

### Other embodiments

As described above, the present disclosure is described by way of the embodiment and modifications and application examples thereof, but the descriptions and the drawings that form part of this disclosure should not be construed to limit the present disclosure. Various alternative embodiments and modifications will be apparent to those skilled in the art from this disclosure. For example, the vertical switching element according to this embodiment is not limited to the planar gate type. The vertical switching element according to this embodiment may be an element that is a trench gate type (e.g., a vertical MOSFET having a structure in which a trench is provided on the side of the front surface 10a of the GaN substrate 10 and a gate electrode 22 is provided in this trench through the gate insulating film 21), has the Ron·Qg of 2Ω·nC or less, and is driven at a driving frequency of 100 kHz or more. Even in such an aspect, the dependence on driving frequency of SW loss can be lowered and the increase in SW loss can be suppressed.

Further, the gate insulating film 42 is not limited to the SiO₂ film and may be another insulating film. For the gate insulating film 42, a silicon oxynitride (SiON) film, a strontium oxide (SrO) film, a silicon nitride (Si₃N₄) film, and an aluminum oxide (Al₂O₃) film are also usable. The gate insulating film 42 is not limited to a single-layer insulating film and may be a stacked-layer film in which several single-layer insulating films are stacked. Further, the vertical switching element according to this embodiment is not limited to the breakdown voltage 1200 V-class element, and may be a higher breakdown voltage element exceeding 1200 V, for example.

Thus, it is a matter of course that this technology includes various embodiments and the like that are not described herein. At least one of various omissions, substitutions, and alternations of the constituent elements can be performed without departing from the gist of the embodiments and the modifications described above. The effects described in this specification are merely examples and are not limited, and other effects may also be involved.

The present disclosure can also take the following configurations.
(1) A nitride semiconductor device including: a nitride semiconductor substrate; and a vertical switching element provided on the nitride semiconductor substrate, in which the vertical switching element has a product of on-resistance Ron and a gate charge amount Qg (Ron·Qg) of 2Ω·nC or less and is driven at a driving frequency of 100 kHz or more.
(2) The nitride semiconductor device according to (1) above, in which the Ron·Qg is 1 Ω·nC or less.
(3) The nitride semiconductor device according to (1) or (2) above, in which the driving frequency is 200 kHz or more and 10 MHz or less.
(4) The nitride semiconductor device according to any one of (1) to (3) above, in which RonA obtained by normalizing the Ron by the area is 2.5 mΩcm² or less.
(5) The nitride semiconductor device according to (4) above, in which the vertical switching element is a vertical MOSFET, and the ratio of the channel resistance of the vertical MOSFET to the RonA is 20% or less.
(6) The nitride semiconductor device according to any one of (1) to (5) above, in which the vertical switching element is a vertical MOSFET, and the vertical MOSFET has JFET resistance of 0.5 mΩcm² or less.
(7) The nitride semiconductor device according to any one of (1) to (6) above, in which the vertical switching element is a planar gate-type vertical MOSFET.
(8) The nitride semiconductor device according to any one of (1) to (7) above, in which the vertical switching element is a vertical MOSFET that is a planar gate type and has a drift region of a super junction structure.
(9) The nitride semiconductor device according to any one of (1) to (8) above, in which the nitride semiconductor substrate has a first surface, and a second surface positioned on the side opposite to the first surface, the vertical switching element is a vertical MOSFET and has a source region provided on the side of the first surface of the nitride semiconductor substrate, a source electrode provided on the side of the first surface and connected to the source region, and a drain electrode provided on the side of the second surface and connected to the nitride semiconductor substrate, and a value of channel resistance of the vertical MOSFET is lower than the total value of contact resistance between the drain electrode and the nitride semiconductor substrate and contact resistance between the source region and the source electrode.
(10) The nitride semiconductor device according to any one of (1) to (9) above, further including a switching circuit containing the vertical switching element.

1. A nitride semiconductor device comprising:
a nitride semiconductor substrate; and
a vertical switching element provided on the nitride semiconductor substrate, wherein
the vertical switching element has a product of on-resistance Ron and a gate charge amount Qg (Ron·Qg) of 2Ω·nC or less and is driven at a driving frequency of 100 kHz or more.

2. The nitride semiconductor device according to claim 1, wherein the Ron·Qg is 1 Ω·nC or less.

3. The nitride semiconductor device according to claim 1, wherein the driving frequency is 200 kHz or more and 10 MHz or less.

4. The nitride semiconductor device according to claim 1, wherein RonA obtained by normalizing the Ron by an area is 2.5 mΩcm² or less.

5. The nitride semiconductor device according to claim 4, wherein
the vertical switching element is a vertical MOSFET, and
a ratio of channel resistance of the vertical MOSFET to the RonA is 20% or less.

6. The nitride semiconductor device according to claim 1, wherein
the vertical switching element is a vertical MOSFET, and
the vertical MOSFET has JFET resistance of 0.5 mΩcm² or less.

7. The nitride semiconductor device according to claim 1, wherein the vertical switching element is a planar gate-type vertical MOSFET.

8. The nitride semiconductor device according to claim 1, wherein the vertical switching element is a vertical MOSFET that is a planar gate type and has a drift region of a super junction structure.

9. The nitride semiconductor device according to claim 1, wherein
the nitride semiconductor substrate has
a first surface, and
a second surface positioned on a side opposite to the first surface,
the vertical switching element is a vertical MOSFET and has
a source region provided on a side of the first surface of the nitride semiconductor substrate,
a source electrode provided on the side of the first surface and connected to the source region, and
a drain electrode provided on a side of the second surface and connected to the nitride semiconductor substrate, and
a value of channel resistance of the vertical MOSFET is lower than a total value of contact resistance between the drain electrode and the nitride semiconductor substrate and contact resistance between the source region and the source electrode.

10. The nitride semiconductor device according to claim 1, further comprising:
a switching circuit containing the vertical switching element.
